(19) United States
(12) Patent Application Publication
(10) Pub. No.: US 2025/0255141 A1
(43) Pub. Date: Aug. 7, 2025

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventor: HYUNEOK SHIN, Yongin-si (KR)

(73) Assignee: Samsung Display Co., LTD., Yongin-si (KR)

(21) Appl. No.: 19/011,948

(22) Filed: Jan. 7, 2025

(30) Foreign Application Priority Data
Feb. 2, 2024 (KR) 10-2024-0016829

(51) Int. Cl. H10K 59/80; H10K 50/19; H10K 59/12; H10K 59/122

(52) U.S. Cl. CPC H10K 59/80517; H10K 50/19; H10K 59/1201; H10K 59/122; H10K 59/80515; H10K 59/80518

(57) ABSTRACT

A display device includes a substrate including a first light emitting area, a second light emitting area, and a non-light emitting area, first and second reflective electrodes disposed in the first and second light emitting areas on the substrate and spaced apart from each other in a first direction, a first pixel electrode on the first reflective electrode and having a width greater than a width of the first reflective electrode, a second pixel electrode on the second reflective electrode and having a width greater than a width of the second reflective electrode, first and second hole auxiliary layers disposed on the first and second pixel electrodes and spaced apart from each other in the first direction, a light emitting layer disposed on the first and second hole auxiliary layers, and a common electrode disposed on the light emitting layer.

### CROSS-REFERENCE TO RELATED APPLICATION(S)

This application claims priority to and benefits of Korean Patent Application No. 10-2024-0016829 under 35 U.S.C. § 119, filed on Feb. 2, 2024, in the Korean Intellectual Property Office (KIPO), the entire contents of which are incorporated herein by reference.

### BACKGROUND

### 1. Technical Field

Embodiments relate to a display device that provides visual information and a method of manufacturing the same.

### 2. Description of the Related Art

As information technology develops, an importance of a display device, which is a connecting medium between users and information, is emerging. Accordingly, use of the display device such as liquid crystal display device, organic light emitting display device, and plasma display device is increasing.

A display device includes a light emitting element, and the light emitting element includes a pixel electrode, a common electrode, and a light emitting layer disposed between the pixel electrode and the common electrode. In order to improve a power efficiency of the light emitting element, functional layers (e.g., a hole auxiliary layer, a hole auxiliary layer, and the like) may be further disposed on and under the light emitting layer.

### SUMMARY

Embodiments provide a display device with improved color mixing defects.

Embodiments provide a method of manufacturing a display device.

A display device according to an embodiment may include a substrate including a first light emitting area, a second light emitting area spaced apart from the first light emitting area in a first direction, and a non-light emitting area located between the first light emitting area and the second light emitting area, a first reflective electrode disposed in the first light emitting area on the substrate, a second reflective electrode disposed in the second light emitting area on the substrate and spaced apart from the first reflective electrode in the first direction, a first pixel electrode disposed in the first light emitting area on the first reflective electrode and having a width greater than a width of first reflective electrode in the first direction, a second pixel electrode disposed in the second light emitting area on the second reflective electrode, space apart from the first pixel electrode in the first direction, and having a width greater than a width of second reflective electrode in the first direction, a first hole auxiliary layer disposed in the first light emitting area on the first pixel electrode, a second hole auxiliary layer disposed in the second light emitting area on the second pixel electrode and spaced apart from the first hole auxiliary layer in the first direction, at least one light emitting layer disposed on the first hole auxiliary layer and the second hole auxiliary layer, and a common electrode disposed on the at least one light emitting layer in the first light emitting area, the second light emitting area, and the non-light emitting area.

In an embodiment, the first pixel electrode may include a first lower pixel electrode disposed on the first reflective electrode and a first upper pixel electrode disposed on the first lower pixel electrode, and the second pixel electrode may include a second lower pixel electrode disposed on the second reflective electrode and a second upper pixel electrode disposed on the second lower pixel electrode.

In an embodiment, the first lower pixel electrode may include silver (Ag).

In an embodiment, the second upper pixel electrode may include indium tin oxide (ITO).

In an embodiment, a thickness of the first lower pixel electrode may be greater than a thickness of the first upper pixel electrode, and a thickness of the second lower pixel electrode may be greater than a thickness of the second upper pixel electrode.

In an embodiment, the thickness of each of the first lower pixel electrode and the second lower pixel electrode may be in a range of about 200 Å to about 1000 Å.

In an embodiment, the thickness of each of the first upper pixel electrode and the second upper pixel electrode may be in a range of about 30 Å to about 100 Å.

In an embodiment, the at least one light emitting layer may include a first light emitting layer disposed between the first hole auxiliary layer and the second hole auxiliary layer, a second light emitting layer disposed on the first light emitting layer, a first charge generating layer disposed between the first light emitting layer and the second light emitting layer in the first light emitting area, and a second charge generating layer disposed between the first light emitting layer and the second light emitting layer in the second light emitting area.

In an embodiment, the first charge generating layer and the second charge generating layer may be spaced apart from each other in the first direction.

In an embodiment, the at least one light emitting layer may further include a third light emitting layer disposed on the second light emitting layer, a third charge generating layer disposed between the second light emitting layer and the third light emitting layer in the first light emitting area, and a fourth charge generating layer disposed between the second light emitting layer and the third light emitting layer in the second light emitting area.

In an embodiment, the third charge generating layer and the fourth charge generating layer may be spaced apart from each other in the first direction.

In an embodiment, the first reflective electrode may include a first lower reflective electrode disposed on the substrate and a first upper reflective electrode disposed on the first lower reflective electrode, and the second reflective electrode may include a second lower reflective electrode disposed on the substrate and a second upper reflective electrode disposed on the second lower reflective electrode.

In an embodiment, in a cross-sectional view, the first lower reflective electrode may have an undercut shape under the first upper reflective electrode and the second lower reflective electrode may have an undercut shape under the second upper reflective electrode.

In an embodiment, the display device may further include a pixel defining layer disposed in the non-light emitting area, a portion of the first light emitting area, and a portion of the second light emitting area on the substrate, and covering a portion of an upper surface of the hole auxiliary layer and a side surface of the hole auxiliary layer.

In an embodiment, the display device may further include a separator disposed in the non-light emitting area on the pixel defining layer.

A method of manufacturing a display device according to an embodiment may include forming a first reflective electrode in a first light emitting area on a substrate including the first light emitting area, a second light emitting area spaced apart from the first light emitting area in a first direction, and a non-light emitting area located between the first light emitting area and the second light emitting area, forming a second reflective electrode spaced apart from the first reflective electrode in the first direction in the second light emitting area on the substrate, forming a first pixel electrode on the first reflective electrode, forming a second pixel electrode spaced apart from the first pixel electrode in the first direction on the second reflective electrode, forming a first hole auxiliary layer on the first pixel electrode, forming a second hole auxiliary layer spaced apart from the first hole auxiliary layer in the first direction on the second pixel electrode, forming a first light emitting layer on the first hole auxiliary layer and the second hole auxiliary layer, forming a first charge generating layer in the first light emitting area on the first light emitting layer, forming a second charge generating layer spaced apart from the first charge generating layer in the first direction in the second light emitting area on the first light emitting layer, and forming a second light emitting layer on the first charge generating layer and the second charge generating layer.

In an embodiment, the first reflective electrode may include a lower reflective electrode disposed on the substrate, an upper reflective electrode disposed on the lower reflective electrode, and the forming of the first reflective electrode may include forming a preliminary lower reflective electrode in the first light emitting area on the substrate, forming the upper reflective electrode in the first light emitting area on the preliminary lower reflective electrode, and removing a portion of the preliminary lower reflective electrode so that a width of the preliminary lower reflective electrode in the first direction is less than a width of the upper reflective electrode in the first direction.

In an embodiment, in the removing of the portion of the preliminary lower reflective electrode, the preliminary lower reflective electrode may be etched to have an undercut shape under the upper reflective electrode in a cross-sectional view to form the lower reflective electrode.

In an embodiment, in the forming of the first hole auxiliary layer and the forming of the second hole auxiliary layer, a deposition material constituting the first hole auxiliary layer and the second hole auxiliary layer may be applied over the first light emitting area, the second light emitting area, and the non-light emitting area, and the first hole auxiliary layer and the second hole auxiliary layer may be spaced apart from each other after the deposition material is applied.

In an embodiment, in the forming of the first charge generating layer and the forming of the second charge generating layer, a deposition material constituting the first charge generating layer and the second charge generating layer may be applied on the first light emitting layer, and the first charge generating layer and the second charge generating layer may be spaced apart from each other after the deposition material is applied.

An electronic device according to an embodiment may include a display device and a power supply providing power to the display device. The display device may include a substrate including a first light emitting area, a second light emitting area spaced apart from the first light emitting area in a first direction, and a non-light emitting area located between the first light emitting area and the second light emitting area, a first reflective electrode disposed in the first light emitting area on the substrate, a second reflective electrode disposed in the second light emitting area on the substrate and spaced apart from the first reflective electrode in the first direction, a first pixel electrode disposed in the first light emitting area on the first reflective electrode and having a width greater than a width of first reflective electrode in the first direction, a second pixel electrode disposed in the second light emitting area on the second reflective electrode, space apart from the first pixel electrode in the first direction, and having a width greater than a width of second reflective electrode in the first direction, a first hole auxiliary layer disposed in the first light emitting area on the first pixel electrode, a second hole auxiliary layer disposed in the second light emitting area on the second pixel electrode and spaced apart from the first hole auxiliary layer in the first direction, at least one light emitting layer disposed on the first hole auxiliary layer and the second hole auxiliary layer, and a common electrode disposed on the at least one light emitting layer in the first light emitting area, the second light emitting area, and the non-light emitting area.

In a display device according to embodiments of the disclosure, the display device may include a substrate including a first light emitting area, a second light emitting area, and a non-light emitting area, a first reflective electrode disposed on the substrate, a second reflective electrode disposed on the substrate, and a pixel electrode disposed on the second reflective electrode. A thickness of the pixel electrode may be greater than or equal to about 200 Å, and accordingly, a hole auxiliary layer, a first charge generating layer, and a second charge generating layer formed on the pixel electrode may be disconnected in the non-light emitting area. Accordingly, color mixing defects due to a generation of a lateral leakage current in the display device may be reduced, and a display quality of the display device may be improved.

In a method of manufacturing the display device according to embodiments of the disclosure, the first reflective electrode having an undercut shape in a cross-sectional view may be formed under the second reflective electrode by removing a portion of a first preliminary reflective electrode. Accordingly, in case that the pixel electrode is formed on the reflective electrode, a reflective electrode may be self-patterned to be disconnected from the non-light emitting area without additional processes.

In case that each of the hole auxiliary layer, the first charge generating layer, and the second charge generating layer is formed on the pixel electrode, the hole auxiliary layer, each of the first charge generating layer, and the second charge generating layer may be formed to be automatically disconnected in the non-light emitting area without additional processes.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of disclosure.

FIG. 2 is a schematic cross-sectional view of a display device taken along line I-I′ of FIG. 1 according to an embodiment.

FIG. 3 is a schematic enlarged cross-sectional view illustrating A1 area of FIG. 2.

FIGS. 4, 5, 6, 7, 8, 9, 10, 11, 12, 13, 14, and 15 are schematic cross-sectional views illustrating a method of manufacturing the display device of FIG. 2.

FIG. 16 is a schematic cross-sectional view of a display device taken along line I-I′ of FIG. 1 according to an embodiment.

FIG. 17 is a schematic enlarged cross-sectional view illustrating A2 area of FIG. 16.

FIG. 18 is a schematic cross-sectional view of a display device taken along line I-I′ of FIG. 1 according to an embodiment.

FIG. 19 is a schematic enlarged cross-sectional view illustrating A3 area of FIG. 18.

FIG. 20 is a block diagram illustrating an electronic device according to an embodiment.

### DETAILED DESCRIPTION OF THE EMBODIMENTS

Unless otherwise specified, the illustrated embodiments are to be understood as providing exemplary features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, display devices in accordance with embodiments will be described in more detail with reference to the accompanying drawings. The same reference numerals are used for the same components in the drawings, and redundant descriptions of the same components will be omitted.

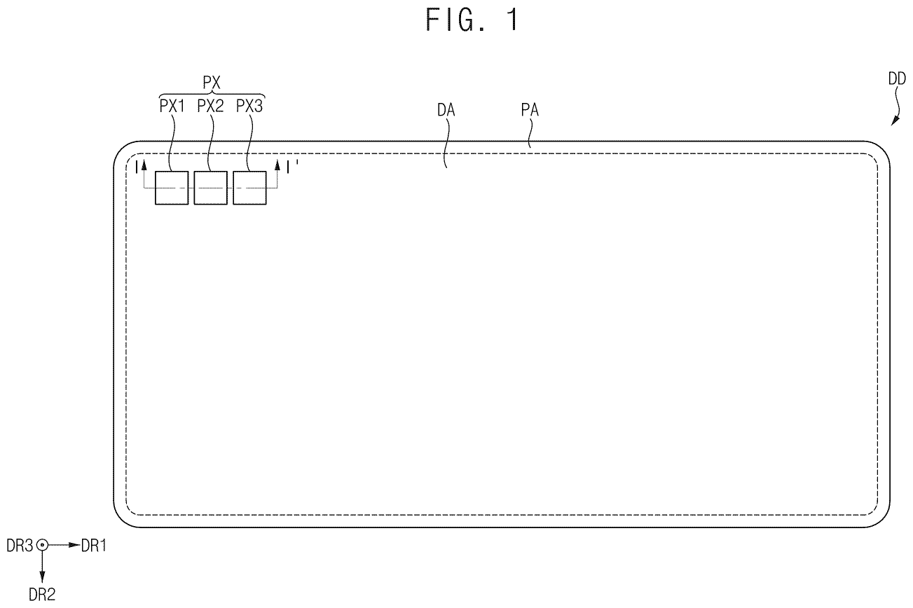

FIG. 1 is a plan view illustrating a display device according to an embodiment of disclosure.

Referring to FIG. 1, a display device DD according to an embodiment of disclosure may include a display area DA and a peripheral area PA. The display area DA may be an area that generates images, and the peripheral area PA may be an area that does not generate images.

In this specification, a plane may be defined by a first direction DR1 and a second direction DR2 intersecting with the first direction DR1. For example, the second direction DR2 may be perpendicular to the first direction DR1. A third direction DR3 may be perpendicular to the plane.

At least one pixel PX may be disposed in the display area DA. The pixel PX may include a first pixel PX1, a second pixel PX2, and a third pixel PX3. For example, the first pixel PX1 may emit a first light, the second pixel PX2 may emit a second light, and the third pixel PX3 may emit a third light. In an embodiment, the first light may be a red light, the second light may be a green light, and the third light may be a blue light. However, the disclosure may not be limited to this. For example, multiple pixels PX may emit yellow, cyan, or magenta lights.

The first, second, and third pixels PX1, PX2, and PX3 may be repeatedly arranged in the first direction DR1 and the second direction DR2 intersecting the first direction DR1 in a plan view. For example, the second pixel PX2 may be adjacent to the first pixel PX1 in the first direction DR1. The third pixel PX3 may be adjacent to the second pixel PX2 in the first direction DR1.

The peripheral area PA may be disposed adjacent to the display area DA. For example, the peripheral area PA may surround at least a portion of the display area DA in a plan view. A driver may be disposed in the peripheral area PA. The driver may provide a signal or a voltage to the pixel PX. For example, the driver may include a data driver, a gate driver, and the like.

In an embodiment, the display device DD may be an ultra-small LED display device (or micro LED display device) that includes an ultra-small LED (or micro LED) as a light emitting element. However, the disclosure may not be limited to this. In another embodiment, the display device DD may be an organic light emitting diode display device including an organic light emitting diode as a light emitting element.

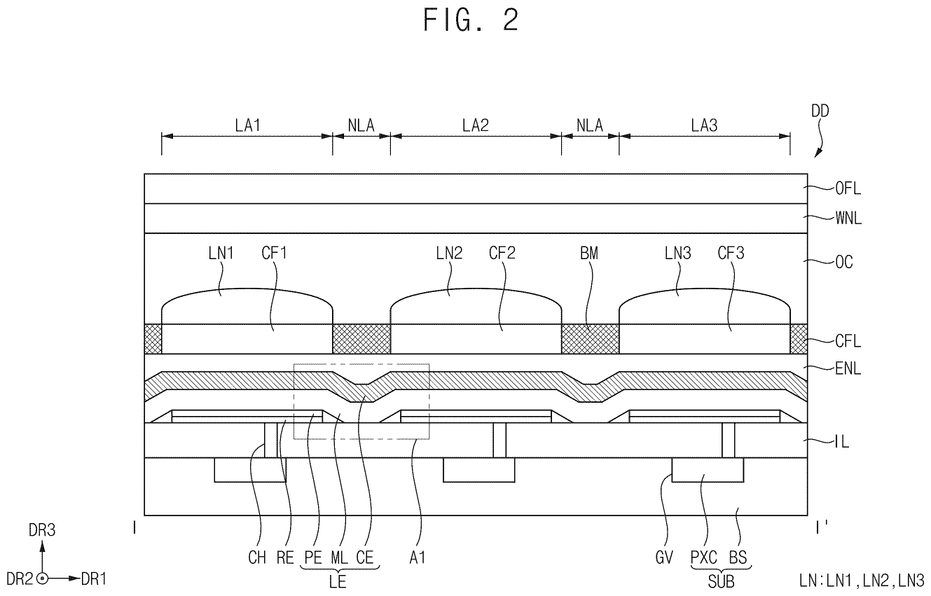

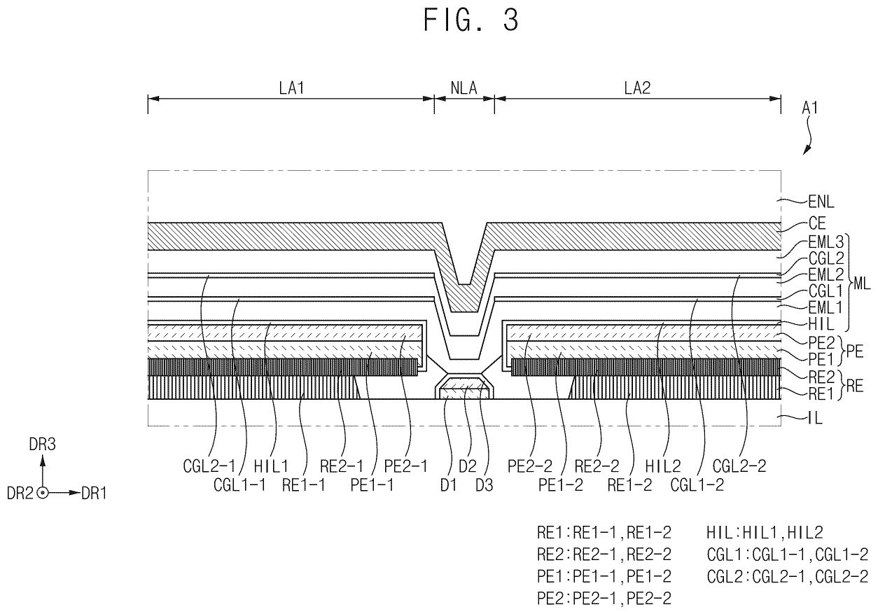

FIG. 2 is a schematic cross-sectional view of a display device taken along line I-I′ of FIG. 1 according to an embodiment. FIG. 3 is a schematic enlarged cross-sectional view illustrating A1 area of FIG. 2.

Referring to FIGS. 2 and 3, the display area DA of FIG. 1 may include a first light emitting area LA1, a second light emitting area LA2, a third light emitting area LA3, and a non-light emitting area NLA. The first pixel PX1 of FIG. 1 that emits the first light may be disposed in the first light emitting area LA1. The second pixel PX2 of FIG. 1 that emits the second light may be disposed in the second light emitting area LA2. The third pixel PX3 of FIG. 1 that emits the third light may be disposed in the third light emitting area LA3. In other words, the first to third light emitting areas LA1, LA2, and LA3 may be areas where light is emitted in the display area DA.

The non-light emitting area NLA may be disposed between two adjacent light emitting areas among the first, second, and third light emitting areas LA1, LA2, and LA3. For example, the non-light emitting area NLA may be disposed between the first light emitting area LA1 and the second light emitting area LA2. The non-light emitting area NLA may be disposed between the second light emitting area LA2 and the third light emitting area LA3. The non-light emitting area NLA may be an area in the display area DA where light is not emitted.

In an embodiment, the first light emitting area LA1, the second light emitting area LA2, and the third light emitting area LA3 may have substantially a same area in a plan view. In another embodiment, the first light emitting area LA1, the second light emitting area LA2, and the third light emitting area LA3 may have different areas.

The display device DD may include a substrate SUB, an insulating structure IL, a reflective electrode RE, a pixel electrode PE, an interlayer ML, a common electrode CE, an encapsulation layer ENL, and a color filter layer CF, a light blocking member BM, first, second, and third micro lenses LN1, LN2, and NL3, a planarization layer OC, a window layer WNL, and an optical functional layer OFL. The color filter layer CFL may include a first color filter CF1, a second color filter CF2, and a third color filter CF3.

The substrate SUB may include a base substrate BS and multiple pixel circuits PXC. In an embodiment, the substrate SUB may be a semiconductor circuit board. The base substrate BS may include a silicon wafer. However, the disclosure may not be limited to this, and the base substrate BS may include a glass. Multiple grooves GRV may be defined in the base substrate BS. The pixel circuit portions PXC may each be accommodated in the grooves GRV.

Each of the pixel circuits PXC may include at least one transistor. Each of the pixel circuits PXC may include at least one capacitor.

The insulating structure IL may be disposed on the substrate SUB. For example, the insulating structure IL may cover the substrate SUB. At least one contact hole CH may be defined in the insulating structure IL. The contact hole CH may penetrate the insulating structure IL in a thickness direction (e.g., the third direction DR3).

The insulating structure IL may include at least one organic layer and at least one inorganic layer. For example, the inorganic layer may be disposed on the substrate SUB and the organic layer may be disposed on the inorganic layer. The inorganic layer may include an inorganic insulating material. For example, the inorganic material may include a silicon oxide, a silicon nitride, a silicon oxynitride, and the like. These may be used alone or in combination with each other. The organic layer may include an organic insulating material. For example, the organic insulating material may include a polyimide-based resin, a polyamide-based resin, and the like. These may be used alone or in combination with each other.

The reflective electrode RE may be disposed on the insulating structure IL. The reflective electrode RE may be electrically connected to the pixel circuits PXC through the contact hole. The reflective electrode RE may receive an anode voltage from the pixel circuits PXC. The reflective electrode RE may reflect light incident from outside of the display device DD or emitted from the interlayer ML.

The reflective electrode RE may include a first reflective electrode RE1 and a second reflective electrode RE2. The second reflective electrode RE2 may be disposed on the first reflective electrode RE1. In an embodiment, the reflective electrode RE may have two-layer structure. However, the disclosure may not be limited to this, a structure of reflective electrode RE may have a single layer or three or more layers.

In an embodiment, a width of the first reflective electrode RE1 in the first direction DR1 may be smaller than a width of the second reflective electrode RE2 in the first direction DR1. For example, the first reflective electrode RE1 may have an undercut shape under the second reflective electrode RE2 in a cross-sectional view. For example, the width of the first reflective electrode RE1 in the first direction DR1 may gradually decrease along the third direction DR3, and an upper surface of the first reflective electrode RE1 may contact a lower surface of the second reflective electrode RE2.

The reflective electrode RE may include a metal material. In an embodiment, the first reflective electrode RE1 and the second reflective electrode RE2 may include different metal materials. For example, the first reflective electrode RE1 may include aluminum (A1), and the second reflective electrode RE2 may include titanium (Ti). However, materials included in the first reflective electrode RE1 and the second reflective electrode RE2 may not be limited to this, and the first reflective electrode RE1 and the second reflective electrode RE2 may include various metal materials.

In an embodiment, a thickness of the first reflective electrode RE1 and a thickness of the second reflective electrode RE2 may be different from each other. For example, the thickness of the first reflective electrode RE1 may be less than the thickness of the second reflective electrode RE2. However, the disclosure may not be limited to this, and the first reflective electrode RE1 may be greater than the second reflective electrode RE2.

In an embodiment, the reflective electrode RE may overlap the first light emitting area LA1 and the second light emitting area LA2 in a plan view. The first reflective electrode RE1 may include a 1-1 reflective electrode RE1-1 overlapping the first light emitting area LA1 and a 1-2 reflective electrode RE1-2 overlapping the second light emitting area LA2 in a plan view. The second reflective electrode RE2 may include a 2-1 reflective electrode RE2-1 overlapping the first light emitting area LA1 and a 2-2 reflective electrode RE2-2 overlapping the second light emitting area LA2 in a plan view. In other words, the reflective electrode RE may not overlap the non-light emitting area NLA.

The 1-1 reflective electrode RE1-1 and the 1-2 reflective electrode RE1-2 may be spaced apart from each other. For example, the 1-1 reflective electrode RE1-1 and the 1-2 reflective electrode RE1-2 may be disposed on the insulating structure IL, and spaced apart from each other in the first direction DR1.

The 2-1 reflective electrode RE2-1 may be disposed on the 1-1 reflective electrode RE1-1. The 2-2 reflective electrode RE2-2 may be disposed on the 1-2 reflective electrode RE1-2. The 2-1 reflective electrode RE2-1 and the 2-2 reflective electrode RE2-2 may be spaced apart from each other.

In this specification, the 1-1 reflective electrode RE1-1 and the 2-1 reflective electrode RE2-1 may be referred to as a first reflective electrode, and the 1-2 reflective electrode RE1-2 and the 2-2 reflective electrode RE2-2 may be referred to as a second reflective electrode. The 1-1 reflective electrode RE1-1 may be referred to as a first lower reflective electrode, and the 2-1 reflective electrode RE2-1 may be referred to as a first upper reflective electrode. The 1-2 reflective electrode RE1-2 may be referred as to a second lower reflective electrode, and the second-second reflective electrode RE2-2 may be referred to as a second upper reflective electrode.

The pixel electrode PE may be disposed on the reflective electrode RE. The pixel electrode PE may contact the reflective electrode RE. Accordingly, the pixel electrode PE may receive the anode voltage from the reflective electrode RE.

The pixel electrode PE may include a first pixel electrode PE1 and a second pixel electrode PE2. The second pixel electrode PE2 may be disposed on the first pixel electrode PE1. In an embodiment, the pixel electrode PE may have a two-layer structure. However, the disclosure may not be limited thereto, and a structure of the pixel electrode PE may have a single layer or three layers.

In an embodiment, the first pixel electrode PE1 and the second pixel electrode PE2 may have different materials from each other. For example, the first pixel electrode PE1 may include silver (Ag), and the second pixel electrode PE2 may include indium tin oxide (ITO). However, materials included in the first pixel electrode PE1 and the second pixel electrode PE2 may not be limited to this, and the first pixel electrode PE1 and the second pixel electrode PE2 may have various materials.

In an embodiment, a thickness of the first pixel electrode PE1 may be greater than a thickness of the second pixel electrode PE2. For example, the thickness of the first pixel electrode PE1 may be about 200 Å and the thickness of the second pixel electrode PE2 may be about 70 Å. However, a thickness of each of the first pixel electrode PE1 and the second pixel electrode PE2 may not be limited to this.

In an embodiment, the thickness of the first pixel electrode PE1 may be less than a thickness of each of the first reflective electrode RE1 and the second reflective electrode RE2. The thickness of the first pixel electrode PE2 may be less than the thickness of each of the first reflective electrode RE1 and the second reflective electrode RE2.

In an embodiment, the pixel electrode PE may overlap the first light emitting area LA1 and the second light emitting area LA2 in a plan view. The first pixel electrode PE1 may include a 1-1 pixel electrode PE1-1 overlapping the first light emitting area LA1 and a 1-2 pixel electrode PE1-2 overlapping the second light emitting area LA2 in a plan view. The second pixel electrode PE2 may include a 2-1 pixel electrode PE2-1 overlapping the first light emitting area LA1 and a 2-2 pixel electrode PE2-2 overlapping the second light emitting area LA2 in a plan view. In other words, the pixel electrode PE may not overlap the non-light emitting area NLA.

The 1-1 pixel electrode PE1-1 may be disposed on the 2-1 reflective electrode RE2-1. The 1-2 pixel electrode PE1-2 may be disposed on the 2-2 reflective electrode RE2-2. The 1-1 pixel electrode PE1-1 and the 1-2 pixel electrode PE1-2 may be spaced apart from each other.

The 2-1 pixel electrode PE2-1 may be disposed on the 1-1 pixel electrode PE1-1. The 2-2 pixel electrode PE2-2 may be disposed on the 1-2 pixel electrode PE1-2. The 2-1 pixel electrode PE2-1 and the 2-2 pixel electrode PE2-2 may be spaced apart from each other.

In this specification, the 1-1 pixel electrode PE1-1 and the 2-1 pixel electrode PE2-1 may be referred to as a first pixel electrode, and the 1-2 pixel electrode PE1-2 and the 2-2 pixel electrode PE2-2 may be referred to as a second pixel electrode. The 1-1 pixel electrode PE1-1 may be referred to as a first lower pixel electrode, and the 2-1 pixel electrode PE2-1 may be referred to as a first upper pixel electrode. The 1-2 pixel electrode PE1-2 may be referred to as a second lower pixel electrode, and the 2-2 pixel electrode PE2-2 may be referred to as a second upper pixel electrode.

In an embodiment, a width of the 1-1 pixel electrode PE1-1 in the first direction DR1 may be greater than a width of the 2-1 reflective electrode RE2-1 in the first direction DR1. A width of the 1-2 pixel electrode PE1-2 in the first direction DR1 may be greater than a width of the 2-2 reflective electrode RE2-2 in the first direction DR1. However, the disclosure may not be limited to this, and widths of the 1-1 pixel electrode PE1-1 and the 1-2 pixel electrode PE1-2 in the first direction DR1 may be same as or smaller than widths of the 2-1 reflective electrode RE2-1 and the 2-2 reflective electrode RE2-2 in the first direction DR1.

In an embodiment, a first dummy layer D1 may be disposed in the non-light emitting area NLA on the insulating structure IL. For example, the first dummy layer D1 may be disposed between the 1-1 reflective electrode RE1-1 and the 1-2 reflective electrode RE1-2.

The first dummy layer D1 and the first pixel electrode PE1 may be formed through a same process and may include a same material. For example, during a process of depositing the first pixel electrode PE1 on the second reflective electrode RE2, a material forming the first pixel electrode PE1 may be incident on an upper surface of the insulating layer IL located between the 2-1 reflective electrode RE2-1 and the 2-2 reflective electrode RE2-2 to form the first dummy layer D1. However, the disclosure may not be limited to this, and the first dummy layer D1 may not be formed on the insulating structure IL.

In an embodiment, the second dummy layer D2 may be disposed in the non-light emitting area NLA on the insulating structure IL. For example, the second dummy layer D2 may be disposed on the first dummy layer D1. The second dummy layer D2 may be disposed between the 1-1 reflective electrode RE1-1 and the 1-2 reflective electrode RE1-2.

A second dummy layer D2 and the second pixel electrode PE2 may be formed through a same process and may include a same material. For example, during a process of depositing the second pixel electrode PE2 on the first pixel electrode PE1, a material forming the second pixel electrode PE2 may be incident on an upper surface of the first dummy layer D1 located between the 1-1 pixel electrode PE1-1 and the 1-2 pixel electrode PE1-2 to form the second dummy layer D2. However, the disclosure may not be limited to this, and the second dummy layer D2 may not be formed on the insulating structure IL.

The interlayer ML may be disposed on the pixel electrode PE. For example, the interlayer ML may be disposed on the second pixel electrode PE2. The interlayer ML may include a hole auxiliary layer HIL, a first light emitting layer EML1, a first charge generating layer CGL1, a second light emitting layer EML2, a second charge generating layer CGL2, and a third light emitting layer EML3.

The hole auxiliary layer HIL may include a hole injection layer and a hole transport layer. For example, the hole transport layer may be disposed on the hole injection layer.

The hole injection layer may include a hole injection material. For example, the hole injection material may include a (N-carbazolyl)triphenylamine (TCTA), a 4,4′,4″-tris[3-methylphenyl(phenyl)amino]triphenylamine (m-MTDATA), and the like. These may be used alone or in combination with each other.

The hole transport layer may include a hole transport material. For example, the hole transport material may include a 4,4′-bis[N-(1-naphthyl)-N-phenylamino]biphenyl (NPB), a 4,4′-bis[N-(3-methylphenyl)-N-phenylamino]biphenyl (TPD), a N,N-di-1-naphthyl-N,N-diphenyl-1,1-biphenyl-4,4-diamine (NPD), a N-phenyl carbazole, polyvinyl carbazole, and the like. These may be used alone or in combination with each other.

The hole auxiliary layer HIL may include a first hole auxiliary layer HIL 1 overlapping the first light emitting area LA1 and a second hole auxiliary layer HIL2 overlapping the second light emitting area LA2 in a plan view. The first hole auxiliary layer HIL1 and the second hole auxiliary layer HIL2 may be spaced apart from each other in the first direction DR1. In other words, the hole auxiliary layer HIL may have a structure that is disconnected in the non-light emitting area NLA.

The first hole auxiliary layer HIL1 may be disposed on the 2-1 pixel electrode PE2-1. The first hole auxiliary layer HIL1 may cover the 2-1 pixel electrode PE2-1. For example, the first hole auxiliary layer HIL1 may cover an upper surface and a side surface of the 2-1 pixel electrode PE2-1.

The second hole auxiliary layer HIL2 may be disposed on the 2-2 pixel electrode PE2-2. The second hole auxiliary layer HIL2 may cover the 2-2 pixel electrode PE2-2. For example, the second hole auxiliary layer HIL2 may cover an upper surface and a side surface of the 2-2 pixel electrode PE2-2.

In an embodiment, a third dummy layer D3 may be disposed in the non-light emitting area NLA on the insulating structure IL. For example, the third dummy layer D3 may be disposed on the second dummy layer D2. The third dummy layer D3 may be disposed between the 1-1 and 1-2 reflective electrodes RE1-1 and RE1-2.

The third dummy layer D3 and the hole auxiliary layer HIL may be formed through a same process and may include a same material. For example, during a process of depositing the hole auxiliary layer HIL on the second pixel electrode PE2, a material forming the hole auxiliary layer HIL may be incident on an upper surface of the second dummy layer D2 located between the 2-1 pixel electrode PE2-1 and the 2-2 pixel electrode PE2-2 to form the third dummy layer D3. However, the disclosure may not be limited to this, and the third dummy layer D3 may not be formed on the insulating structure IL.

The first light emitting layer EML1 may be disposed on the hole auxiliary layer HIL. The first light emitting layer EML1 may overlap the first hole auxiliary layer HIL1 and the second hole auxiliary layer HIL2 in a plan view. In an embodiment, the first light emitting layer EML1 may be disposed over the first light emitting area LA1, the second light emitting area LA2, and the non-light emitting area NLA. In another embodiment, the first light emitting layer EML1 may be disposed in the first light emitting area LA1 and the second light emitting area LA2. For example, the first light emitting layer EML1 may not be disposed in the non-light emitting area NLA and have a disconnected structure in the non-light emitting area NLA.

The first light emitting layer EML1 may emit the first light in a red wavelength band. However, a color of light emitted from the first emitting layer EML1 may not be limited to this, and the light emitted from the first emitting layer EML1 may have various colors.

The first charge generating layer CGL1 may be disposed on the first light emitting layer EML1. The first charge generating layer CGL1 may include an n-type aryl amine layer and a p-type metal oxide layer, and the n-type aryl amine layer and the p-type metal oxide layer may form a complex by generating an oxidation-reduction reaction and generate a charge in case that a voltage is applied on the n-type aryl amine layer and the p-type metal oxide layer. The first charge generating layer CGL1 may include an arylamine-based organic compound, a metal, a metal oxide, a metal carbide, a metal fluoride, and the like. These may be used alone or in combination with each other. For example, aryl amine-based organic compounds may include a α-NPD, a 2-TNATA, a TDATA, a MTDATA, a spiro-TAD, and sprio-NPB, the metal may include Cs, Mo, V, Ti, and W., Ba or Li, and the like., and the metal oxide, metal carbide, and metal fluoride may include Re₂O₇, MoO₃, V₂O₅, WO₃, TiO₂, Cs₂CO₃, BaF, LiF, CsF, and the like.

The first charge generating layer CGL1 may include a 1-1 charge generating layer CGL1-1 overlapping the first light emitting area LA1 and a 1-2 charge generating layer CGL1-2 overlapping the second light emitting area LA2 in a plan view. The 1-1 charge generating layer CGL1-1 and the 1-2 charge generating layer CGL1-2 may be spaced apart from each other in the first direction DR1. In other words, the first charge generating layer CGL1 may have a structure that is disconnected in the non-light emitting area NLA.

In this specification, the 1-1 charge generating layer CGL1-1 may be referred to as a first charge generating layer, and the 1-2 charge generating layer CGL1-2 may be referred to as a second charge generating layer.

The second light emitting layer EML2 may be disposed on the first charge generating layer CGL1. The second light emitting layer EML2 may overlap the 1-1 charge generating layer CGL1-1 and the 1-2 charge generating layer CGL1-2 in a plan view. In an embodiment, the second light emitting layer EML2 may be disposed over the first light emitting area LA1, the second light emitting area LA2, and the non-light emitting area NLA. In another embodiment, the second light emitting layer EML2 may be disposed in the first light emitting area LA1 and the second light emitting area LA2. For example, the second light emitting layer EML2 may not be disposed in the non-light emitting area NLA, but may have a disconnected structure in the non-light emitting area NLA.

The second light emitting layer EML2 may emit the second light in the green wavelength band. The second light emitted from the second emitting layer EML2 may be mixed with the first light emitted from the first emitting layer EML1. For example, the first light, which is red, and the second light, which is green, may be mixed to produce yellow light. However, a color of light emitted from the second emitting layer EML2 may not be limited to this, and the light emitted from the second emitting layer EML2 may have various colors.

The second charge generating layer CGL2 may be disposed on the second light emitting layer EML2. A material included in the second charge generating layer CGL2 and a material included in the first charge generating layer CGL1 may be substantially the same.

The second charge generating layer CGL2 may include a 2-1 charge generating layer CGL2-1 overlapping the first light emitting area LA1 and a 2-2 charge generating layer CGL2-2 overlapping the second light emitting area in a plan view. The 2-1 charge generating layer CGL2-1 and the 2-2 charge generating layer CGL2-2 may be spaced apart from each other in the first direction DR1. In other words, the second charge generating layer CGL2 may have a structure that is disconnected in the non-light emitting area NLA.

In this specification, the 2-1 charge generating layer CGL2-1 may be referred to as a third charge generating layer, and the 2-2 charge generating layer CGL2-2 may be referred to as a fourth charge generating layer.

The third light emitting layer EML3 may be disposed on the second charge generating layer CGL2. The third light emitting layer EML3 may overlap the 2-1 charge generating layer CGL2-1 and the 2-2 charge generating layer CGL2-2 in a plan view. In an embodiment, the third light emitting layer EML3 may be disposed over the first light emitting area LA1, the second light emitting area LA2, and the non-light emitting area NLA. In another embodiment, the third light emitting layer EML3 may be disposed only in the first light emitting area LA1 and the second light emitting area LA2. For example, the third light emitting layer EML3 may not be disposed in the non-light emitting area NLA, but may have a structure disconnected in the non-light emitting area NLA.

The third light emitting layer EML3 may emit the third light in a blue wavelength band. The third light emitted from the third emitting layer EML3 may be mixed with the first light emitted from the first emitting layer EML1 and the second light emitted from the second emitting layer EML2. For example, the red first light, the green second light, and the blue third light may be mixed together to produce white light. However, a color of light emitted from the third emitting layer EML3 may not be limited to this, and the light emitted from the third emitting layer EML3 may have various colors.

As described above, the display device DD may include first, second, third light emitting layers EML1, EML2, and EML3. In other words, the display device DD may have a structure in which at least two or more light emitting layers are stacked each other. However, the disclosure may not be limited to this, and the display device DD may have one light emitting layer.

The common electrode CE may be disposed on the third light emitting layer EML3. An electron auxiliary layer may be disposed between the common electrode CE and the third emitting layer EML3. In an embodiment, the electron auxiliary layer may be disposed over the first light emitting area LA1, the second light emitting area LA2, and the non-light emitting area NLA. In another embodiment, the electron auxiliary layer may be disposed in the first light emitting area LA1 and the second light emitting area LA2. For example, the electron auxiliary layer may have a structure disconnected in the non-light emitting area NLA. The electron auxiliary layer may include an electron transport layer and an electron injection layer. For example, the electron injection layer may be disposed on the electron transport layer.

The electron transport layer may include an electron transport material. For example, the electron transport material may include Alq3, 2-(4-biphenylyl)-5-(4-tert-butylphenyl-1,3,4-oxydiazole (PBD), bis(2-methyl- These may include a 8-quinolinolato)-4-phenylphenolato-aluminum (BAlq), bathocuproine (BCP), a triazole (TAZ), phenylquinozaline, and the like. These may be used alone or in combination with each other.

The electron injection layer may include an electron injection material. For example, the electron injection material may include LiF, CsF, and the like. These may be used alone or in combination with each other.

The common electrode CE may be disposed over the first light emitting area LA1, the second light emitting area LA2, and the non-light emitting area NLA. The common electrode CE may include a metal, a metal alloy, a metal nitride, a conductive metal oxide, a transparent conductive material, or the like. These may be used alone or in combination with each other.

The pixel electrode PE, the interlayer ML, and the common electrode CE may form a light emitting element LE.

The encapsulation layer ENL may be disposed on the common electrode CE. The encapsulation layer ENL may cover the light emitting element LE. The encapsulation layer ENL may prevent foreign impurities from penetrating into the light emitting element LE.

The encapsulation layer ENL may include at least one inorganic layer and at least one organic layer. For example, the encapsulation layer ENL may include a first inorganic layer disposed on the common electrode CE, the organic layer disposed on the first inorganic layer, and a second inorganic layer disposed on the organic layer.

The color filter layer CFL may be disposed on the encapsulation layer ENL. The light blocking member BM may be disposed on the encapsulation layer ENL. The light blocking member BM may define the first light emitting area LA1, the second light emitting area LA2, and the third light emitting area LA3. For example, the light blocking member BM may define multiple openings dividing the first, second and third light emitting areas LA1, LA2, and LA3. Accordingly, the light blocking member BM may not overlap the first to third light emitting areas LA1, LA2, and LA3 in a plan view. The light blocking member BM may include an organic material and/or an inorganic material including a black pigment, a black dye, or the like.

The first to third color filters CF1, CF2, and CF3 may each be disposed in the openings defined by the light blocking member BM.

The first color filter CF1 may overlap the first light emitting area LA1 in a plan view. The first color filter CF1 may transmit the first light and absorb or block the second light and the third light. For example, the first color filter CF1 may transmit light in a red wavelength band and absorb or block light in other wavelength bands such as green and blue, but the disclosure may not be limited this.

The second color filter CF2 may overlap the second light emitting area LA2 in a plan view. The second color filter CF2 may transmit the second light and absorb or block the first light and the third light. For example, the second color filter CF2 may transmit light in a green wavelength band and absorb or block light in other wavelength bands such as blue and red, but the disclosure may not be limited this.

The third color filter CF3 may overlap the third light emitting area LA3 in a plan view. The third color filter CF3 may transmit the third light and absorb or block the first light and the second light. For example, the third color filter CF3 may transmit light in a blue wavelength band and absorb or block light in other wavelength bands such as green and red, but the disclosure may not be limited this.

Micro lenses LN may be disposed on the color filter layer CFL. The micro lenses LN may be disposed on each of the first, second, and third color filters CF1, CF2, and CF3. For example, the micro lenses LN may overlap each of the first, second, and third light emitting areas LA1, LA2, and LA3 in a plan view. Each of the micro lenses LN may have a shape of a convex lens. Micro lenses LN may improve a light extraction efficiency.

The planarization layer OC may be disposed on the micro lenses LN. The planarization layer OC may have a substantially flat upper surface. For example, the planarization layer OC may include an organic material.

The window layer WNL may be disposed on the planarization layer OC. The window layer WNL may protect the interlayer ML, the substrate SUB, and the like. For example, the window layer WNL may include a glass.

The optical functional layer OFL may be disposed on the window layer WNL. For example, the optical functional layer OFL may be a polarizing layer. The optical functional layer OFL may reduce an external light reflection of the display device DD. As the external light reflection is reduced, a visibility of the display device DD may be improved.

In case that a thickness of the first pixel electrode PE1 is less than or equal to about 200 Å, the hole auxiliary layer HIL, the first charge generating layer CGL1, and the second charge generating layer CGL2 formed on the first pixel electrode PE1 may not be disconnected in the non-light emitting area NLA. Accordingly, a lateral leakage current may be generated between adjacent pixels among the pixels PX.

As described above, a thickness of the first pixel electrode PE1 included in the display device DD may be greater than or equal to about 200 Å. For example, the thickness of each of the 1-1 pixel electrode PE1-1 and the 1-2 pixel electrode PE1-2 may be in a range of about 200 Å to about 1000 Å. Accordingly, the hole auxiliary layer HIL, the first charge generating layer CGL1, and the second charge generating layer CGL2 formed on the first pixel electrode PE1 may be disconnected in the non-light emitting area NLA. Accordingly, color mixing defects due to the generation of the lateral leakage current in the display device DD may be reduced, and a display quality of the display device DD may be improved. In addition, the thickness of each of the 2-1 pixel electrode PE2-1 and the 2-2 pixel electrode PE2-2 may be in a range of about 30 Å to about 100 Å.

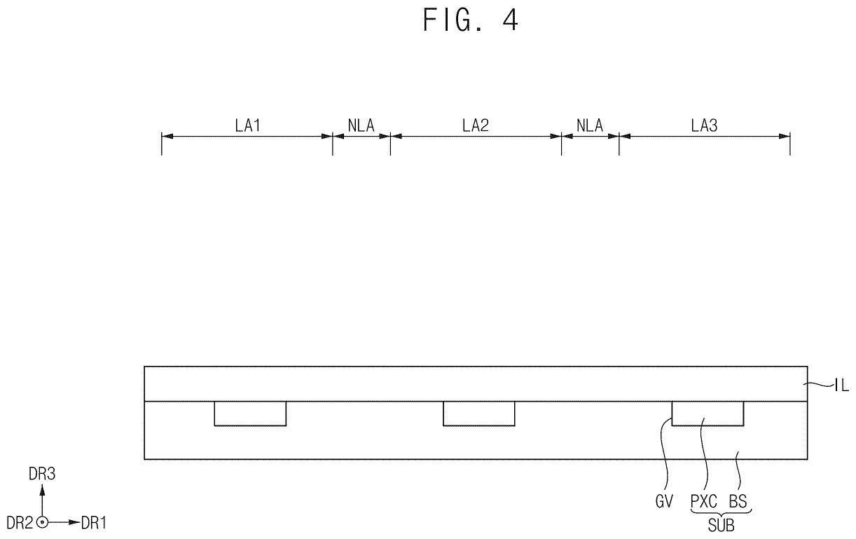

FIGS. 4, 5, 6, 7, 8, 9, 10, 11, 12, 13, 14, and 15 are schematic cross-sectional views illustrating a method of manufacturing the display device of FIG. 2.

Hereinafter, contents overlapping contents described with reference to FIGS. 2 and 3 will be omitted or simplified.

Referring to FIG. 4, the insulating structure IL may be formed on the substrate SUB. The insulating structure IL may be formed over the first light emitting area LA1, the second light emitting area LA2, and the non-light emitting area NLA on the substrate SUB. The insulating structure IL may cover the base substrate BS and the pixel circuits PXC each included in the substrate SUB.

In an embodiment, as described above, the insulating structure IL may include at least one organic layer and at least one inorganic layer. Accordingly, after at least one inorganic layer is formed on the substrate SUB, at least one organic layer may be formed on the inorganic layer. The organic layer may have a substantially flat upper surface.

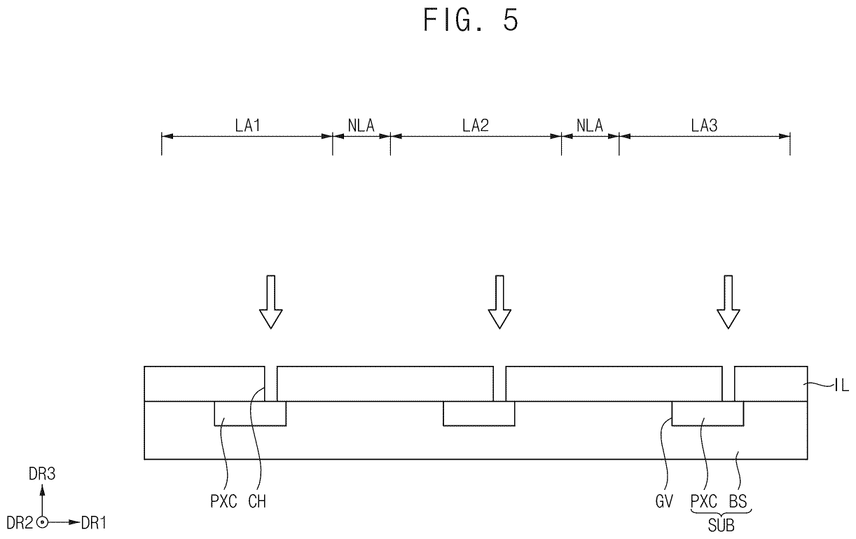

Referring to FIG. 5, a portion of the insulating structure IL may be removed and a portion of an upper surface of the substrate SUB may be exposed. For example, a portion of the insulating structure IL may be removed to form a contact hole CH exposing at least a portion of the pixel circuits PXC.

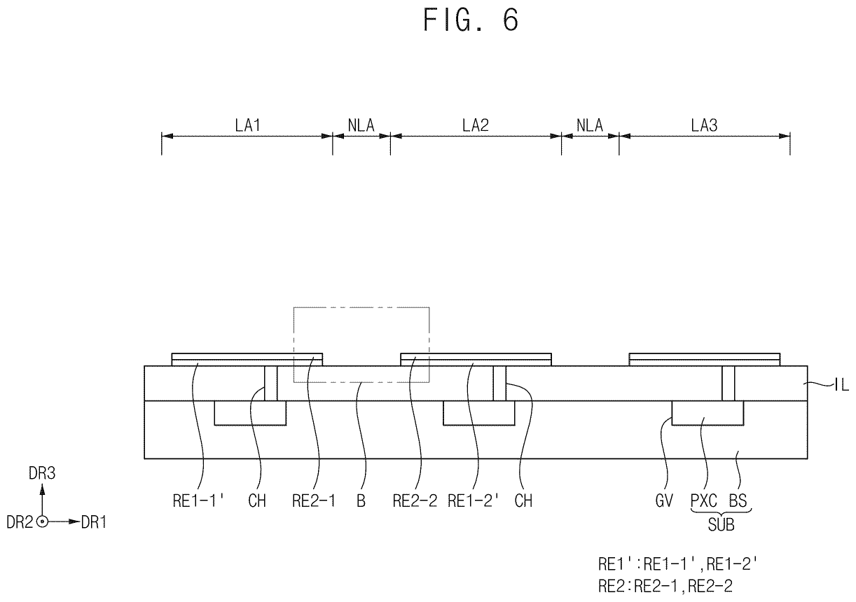

Referring to FIG. 6, a first preliminary reflective electrode RE1′ may be formed on the insulating structure IL. The second reflective electrode RE2 may be formed on the first preliminary reflective electrode RE1′. For example, both the first preliminary reflective electrode RE1′ and the second reflective electrode RE may overlap the first, second, and third light emitting areas LA1, LA2, and LA3 in a plan view. In other words, neither the first preliminary reflective electrode RE1′ nor the second reflective electrode RE may overlap the non-light emitting areas NLA. A 1-1 preliminary reflective electrode RE1-1′ and a 1-2 preliminary reflective electrode RE1-2′ may be spaced apart from each other in the first direction DR1. The 2-1 reflective electrode RE2-1 and the 2-2 preliminary reflective electrode RE2-2 may be spaced apart from each other in the first direction DR1.

For example, a material forming the first preliminary reflective electrode RE1′ may be entirely formed over the first, second, and third light emitting areas LA1, LA2, and LA3 and the non-light emitting area NLA on the insulating structure IL. Thereafter, a material forming the second reflective electrode RE2 may be applied over the first, second, and third light emitting areas LA1, LA2, and LA3 and the non-light emitting area NLA on the material forming the first preliminary reflective electrode RE1′. Thereafter, the material forming the first preliminary reflective electrode RE1′ overlapping the non-light emitting area NLA may be removed to form the first preliminary reflective electrode RE1′. A portion of the material forming the second reflective electrode RE2 overlapping the non-light emitting area NLA may be removed to form the second reflective electrode RE2.

In an embodiment, a width of the first preliminary reflective electrode RE1′ in the first direction DR1 and a width of the second preliminary reflective electrode RE2′ in the first direction DR1 may be substantially the same. The material forming the first preliminary reflective electrode RE1′ may fill the contact hole CH. Accordingly, the first preliminary reflective electrode RE1′ may be electrically connected to the pixel circuits PXC.

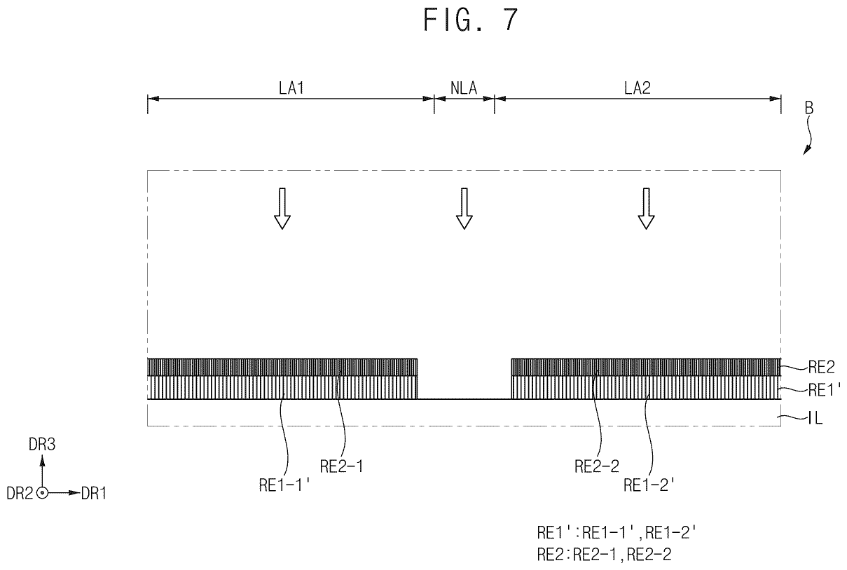

FIG. 7 is a schematic enlarged cross-sectional view of area B of FIG. 6.

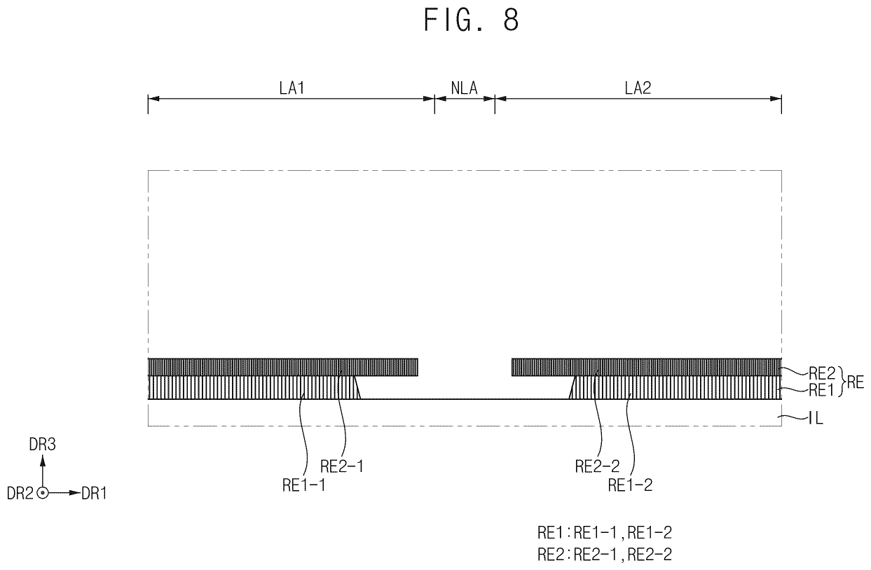

Referring to FIGS. 7 and 8, a portion of the first preliminary reflective electrode RE1′ may be removed to form the first reflective electrode RE1. For example, a portion of the first preliminary reflective electrode RE1′ may be removed through dry etching. The width of the first reflective electrode RE1 formed by removing a portion of the first preliminary reflective electrode RE1′ in the first direction DR1 may be smaller than the width of the second reflective electrode RE2 in the first direction DR1. For example, a portion of the first preliminary reflective electrode RE1′ may be removed through a dry etching, and the first reflective electrode RE1 may be formed to have an undercut shape in a cross-sectional view under the second reflective electrode RE2.

While performing a step of the manufacturing method illustrated in FIGS. 6, 7, and 8, the 1-1 preliminary reflective electrode RE1-1′ may be referred to as a preliminary lower reflective electrode.

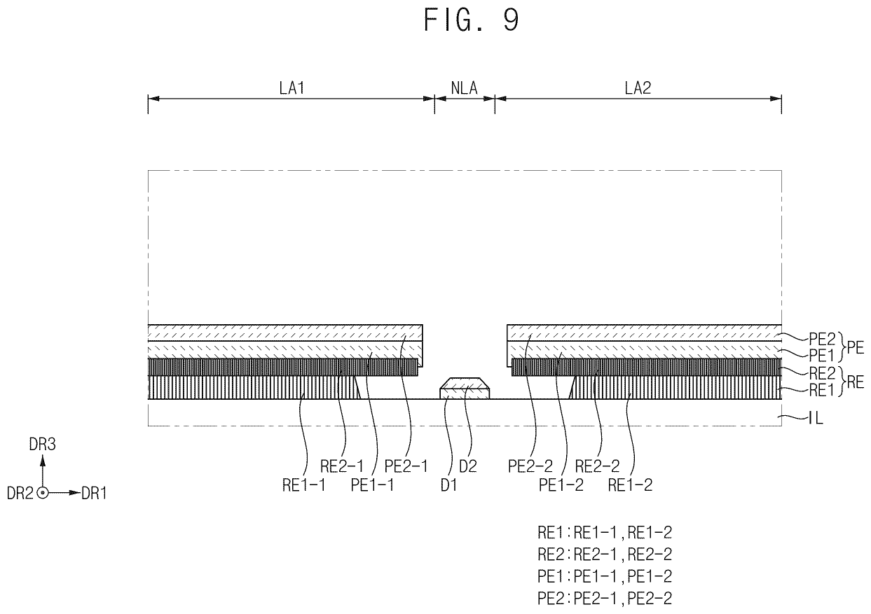

Referring to FIG. 9, the first pixel electrode PE1 may be formed on the second reflective electrode RE2. For example, the 1-1 pixel electrode PE1-1 may be formed on the 2-1 reflective electrode RE2-1. The 1-2 pixel electrode PE1-2 may be formed on the 2-2 reflective electrode RE2-2.

For example, a material forming the first pixel electrode PE1 may be incident on the first light emitting area LA1, the second light emitting area LA2, and the non-light emitting area NLA. As the first reflective electrode RE1 has an undercut shape in a cross-sectional view under the second reflective electrode RE2, the material forming the first pixel electrode PE1 may form the 1-1 pixel electrode PE1-1 and the 1-2 pixel electrode PE1-2 which are spaced apart from each other in the first direction DR1. In case that the material forming the first pixel electrode PE1 is incident on the non-light emitting area NLA, the first dummy layer D1 may be formed on the insulating structure IL. However, the disclosure may not be limited to this, and the material forming the first pixel electrode PE1 may not be incident on the non-light emitting area NLA.

The second pixel electrode PE2 may be formed on the first pixel electrode PE1. For example, the 2-1 pixel electrode PE2-1 may be formed on the 1-1 pixel electrode PE1-1. The 2-2 pixel electrode PE2-2 may be formed on the 1-2 pixel electrode PE1-2.

For example, a material forming the second pixel electrode PE2 may be incident on the first light emitting area LA1, the second light emitting area LA2, and the non-light emitting area NLA. As the first reflective electrode RE1 has an undercut shape in a cross-sectional view under the second reflective electrode RE2, the material forming the second pixel electrode PE2 may form the 2-1 pixel electrode PE2-1 and the 2-2 pixel electrode PE2-2 which are spaced apart from each other in the first direction DR1. In case that the material forming the second pixel electrode PE2 is incident on the non-light emitting area NLA, the second dummy layer D2 may be formed on the first dummy layer D1. However, the disclosure may not be limited to this, and the material forming the second pixel electrode PE2 may not be incident on the non-light emitting area NLA.

In an embodiment, materials forming the first pixel electrode PE1 and the second pixel electrode PE2 may be formed through a sputtering method, a thermal evaporator method, or the like. However, a deposition method may not be limited to this, and the first pixel electrode PE1 and the second pixel electrode PE2 may be deposited using various methods.

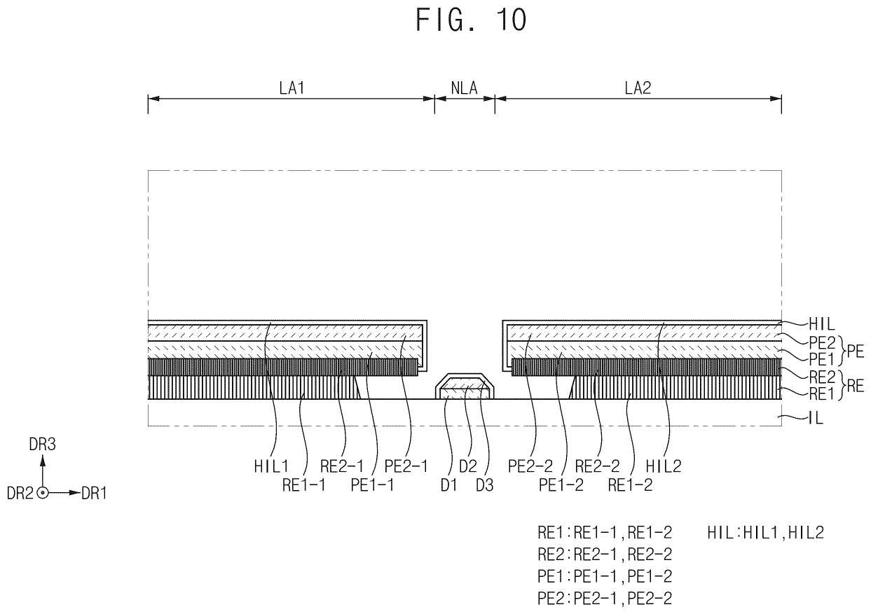

Referring to FIG. 10, the hole auxiliary layer HIL may be formed on the second pixel electrode PE2. For example, the first hole auxiliary layer HIL1 may be formed on the 2-1 pixel electrode PE2-1. The second hole auxiliary layer HIL2 may be formed on the 2-2 pixel electrode PE2-2.

In an embodiment, a deposition material forming the first hole auxiliary layer HIL 1 and the second hole auxiliary layer HIL2 may be deposited over the first light emitting area LA1, the second light emitting area LA2, and the non-light emitting area NLA, and while the deposition material is being applied, the first hole auxiliary layer HIL1 and the second hole auxiliary layer HIL2 may be spaced apart from each other.

For example, the deposition material forming the hole auxiliary layer HIL may be incident on the first light emitting area LA1, the second light emitting area LA2, and the non-light emitting area NLA. As the first reflective electrode RE1 has an undercut shape in a cross-sectional view under the second reflective electrode RE2, the material forming the hole auxiliary layer HIL may form the hole auxiliary layer HIL1 and the second hole auxiliary layer HIL2 which are spaced apart from each other in the first direction DR1. In case that the material forming the hole auxiliary layer HIL is incident on the non-light emitting area NLA, the third dummy layer D3 may be formed on the second dummy layer D2. However, the disclosure may not be limited to this, and the material forming the hole auxiliary layer HIL may not be incident on the non-light emitting area NLA.

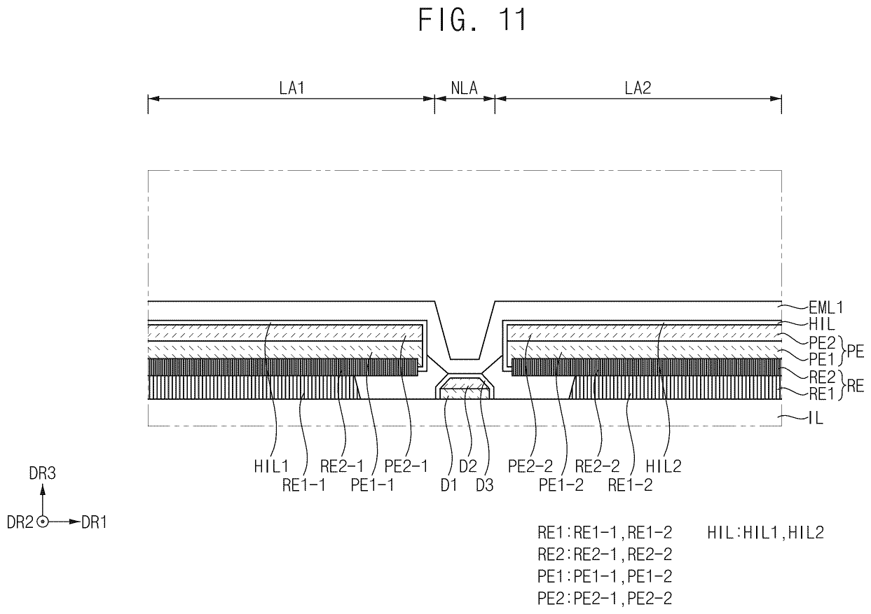

Referring to FIG. 11, the first light emitting layer EML1 may be formed on the hole auxiliary layer HIL. In an embodiment, the first light emitting layer EML1 may be formed entirely over the first light emitting area LA1, the second light emitting area LA2, and the non-light emitting area NLA. In another embodiment, the first light emitting layer EML1 may be formed in the first light emitting area LA1 and the second light emitting area LA2. For example, the first light emitting layer EML1 may be formed on the hole auxiliary layer HIL to be disconnected in the non-light emitting area NLA.

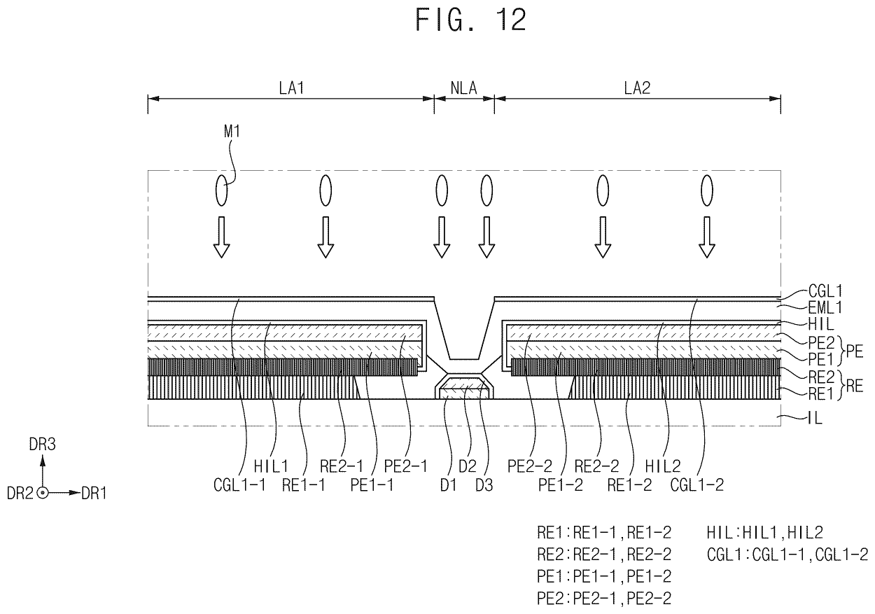

Referring to FIG. 12, the first charge generating layer CGL1 may be formed on the first light emitting layer EML1. For example, the first charge generating layer CGL1 may be formed on the first light emitting area LA1 and the second light emitting area LA2. In other words, the first charge generating layer CGL1 may be formed on the first light emitting layer EML1 to be disconnected in the non-light emitting area NLA.

In an embodiment, a first material M1 constituting the 1-1 charge generating layer CGL1-1 and the 1-2 charge generating layer CGL1-2 may be applied on the first emitting layer EML1. In case that the first material M1 is applied, the 1-1 charge generating layer CGL1-1 and the 1-2 charge generating layer CGL1-2 may be spaced apart from each other.

For example, the first material M1 forming the first charge generating layer CGL1 may be incident on the first light emitting layer EML1. As the first reflective electrode RE1 has an undercut shape in cross-section view under the second reflective electrode RE2, the first material M1 may be deposited on the first emitting layer EML1 overlapping the first light emitting area LA1 and the second light emitting area LA2 in a plan view. In other words, the first material M1 may not be deposited on the first light emitting layer EML1 overlapping the non-light emitting area NLA. Accordingly, the 1-1 charge generating layer CGL1-1 and the 1-2 charge generating layer CGL1-2 may be spaced apart from each other in the first direction DR1.

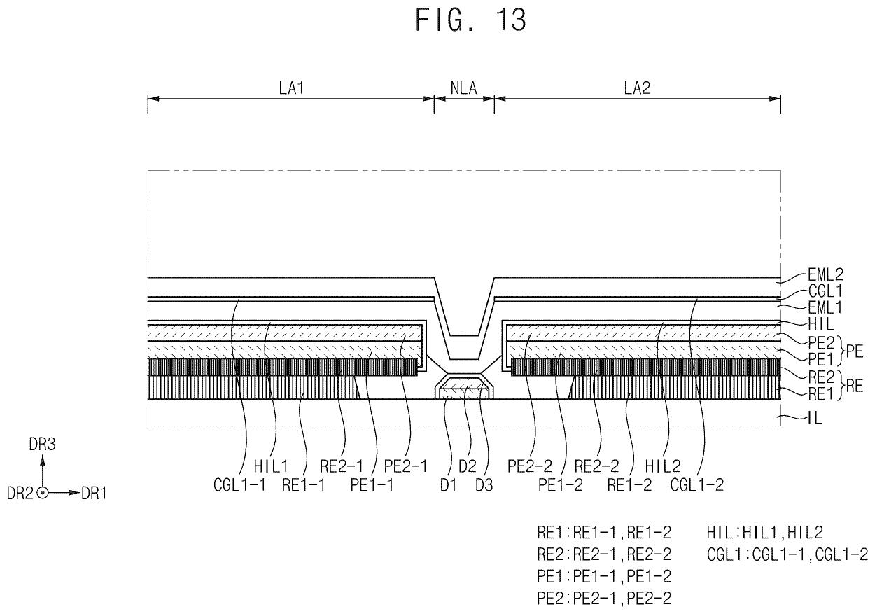

Referring to FIG. 13, the second light emitting layer EML2 may be formed on the first charge generating layer CGL1. In an embodiment, the second light emitting layer EML2 may be formed entirely over the first light emitting area LA1, the second light emitting area LA2, and the non-light emitting area NLA. In another embodiment, the second light emitting layer EML2 may be formed in the first light emitting area LA1 and the second light emitting area LA2. For example, the second light emitting layer EML2 may be formed on the first charge generating layer CGL1 to be disconnected in the non-light emitting area NLA.

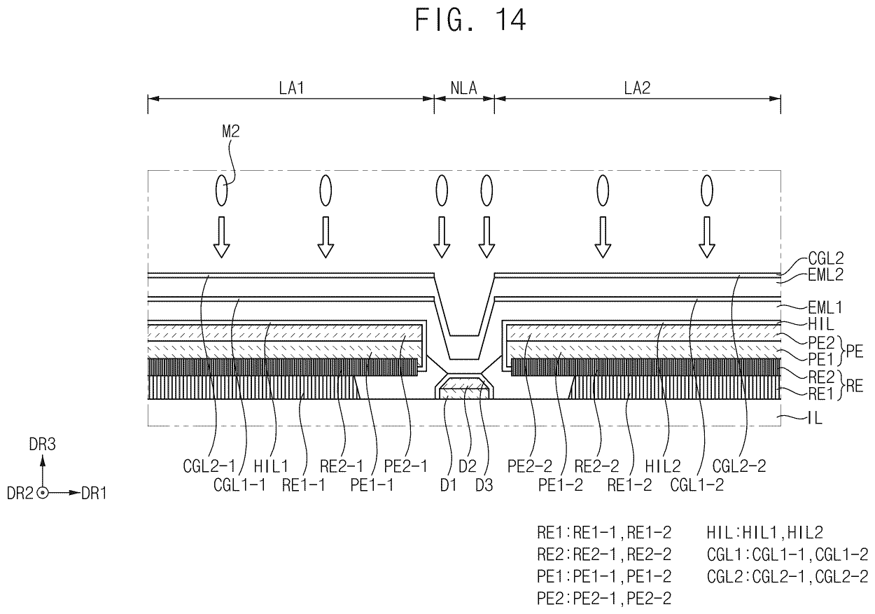

Referring to FIG. 14, the second charge generating layer CGL2 may be formed on the second light emitting layer EML2. For example, the second charge generating layer CGL2 may be formed on the first light emitting area LA1 and the second light emitting area LA2. In other words, the second charge generating layer CGL2 may be formed on the second light emitting layer EML2 to be disconnected in the non-light emitting area NLA.

In an embodiment, a second material M2 constituting the 2-1 charge generating layer CGL2-1 and the 2-2 charge generating layer CGL2-2 may be applied on the second light emitting layer EML2. In case that the second material M2 is applied, the 2-1 charge generating layer CGL2-1 and the 2-2 charge generating layer CGL2-2 may be spaced apart from each other.

For example, a second material M2 forming the second charge generating layer CGL2 may be incident on the second light emitting layer EML2. As the first reflective electrode RE1 has an undercut shape in a cross-sectional view under the second reflective electrode RE2, the second material M2 may be deposited on the second light emitting layer EML2 overlapping the first light emitting area LA1 and the second light emitting area LA2 in a plan view. In other words, the second material M2 may not be deposited on the second light emitting layer EML2 overlapping the non-light emitting area NLA. Accordingly, the 2-1 charge generating layer CGL2-1 and the 2-2 charge generating layer CGL2-2 may be spaced apart from each other in the first direction DR1.

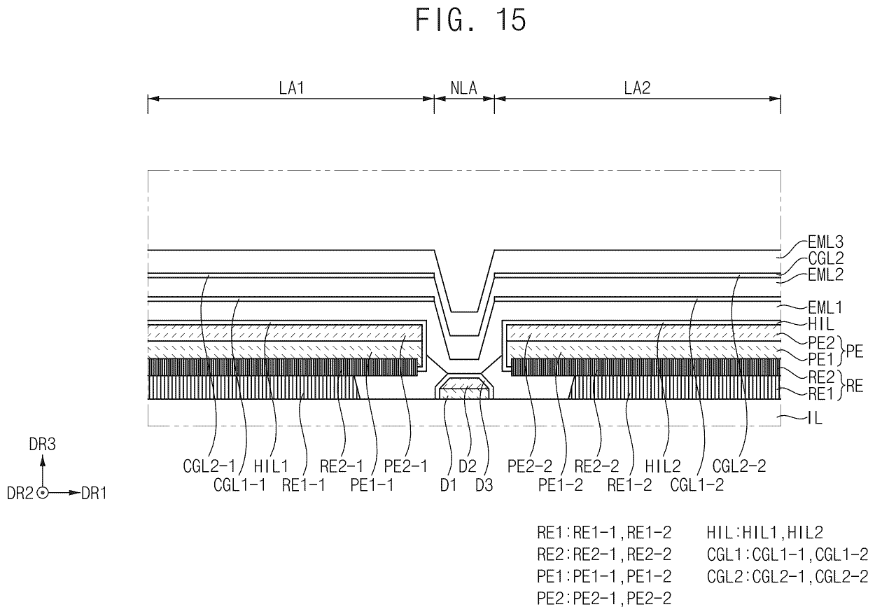

Referring to FIG. 15, the third light emitting layer EML3 may be formed on the second charge generating layer CGL2. In an embodiment, the third light emitting layer EML3 may be formed entirely over the first light emitting area LA1, the second light emitting area LA2, and the non-light emitting area NLA. In another embodiment, the third light emitting layer EML3 may be formed in the first light emitting area LA1 and the second light emitting area LA2. For example, the third light emitting layer EML3 may be formed on the second charge generating layer CGL2 to be disconnected in the non-light emitting area NLA.

The common electrode CE, the encapsulation layer ENL, the color filter layer CFL, the planarization layer OC, the window layer WNL, and the optical function layer OFL of FIG. 2 may be formed on the third light emitting layer EML3. Afterwards, the display device DD of FIG. 1 may be manufactured.

As described above, in the method of manufacturing the display device DD, a portion of the first preliminary reflective electrode RE1′ may be removed to form the first reflective electrode RE1 having an undercut shape in a cross-sectional view. Accordingly, in case that the pixel electrode PE is formed on the reflective electrode RE, a self-patterning may be performed so that the reflective electrode RE is disconnected in the non-light emitting area NLA without additional processes (e.g., an etching process).

In case that each of the hole auxiliary layer HIL, the first charge generating layer CGL1, and the second charge generating layer CGL2 is formed, each of the hole auxiliary layer HIL, the first charge generating layer CGL1, and the second charge generating layer CGL2 may be formed to be automatically disconnected in the non-light emitting NLA area without additional processes.

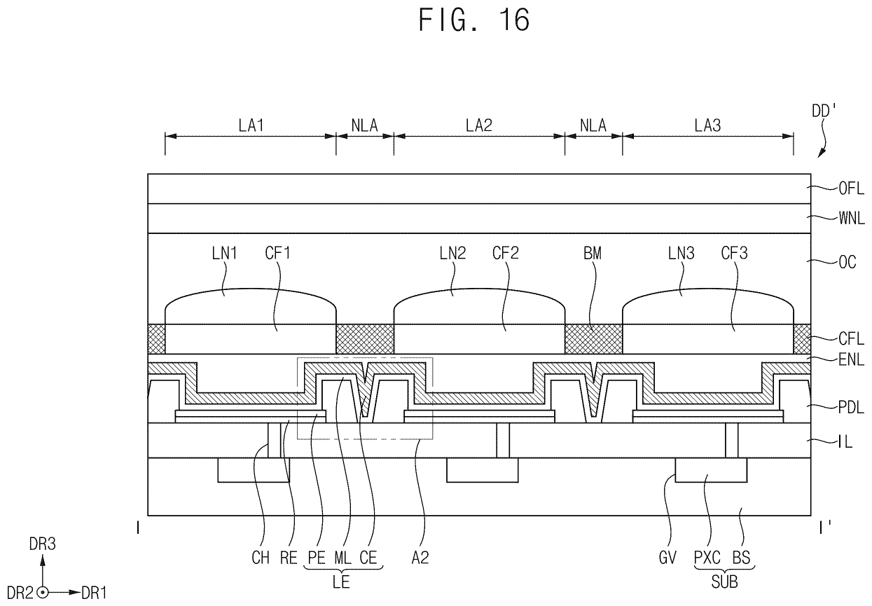

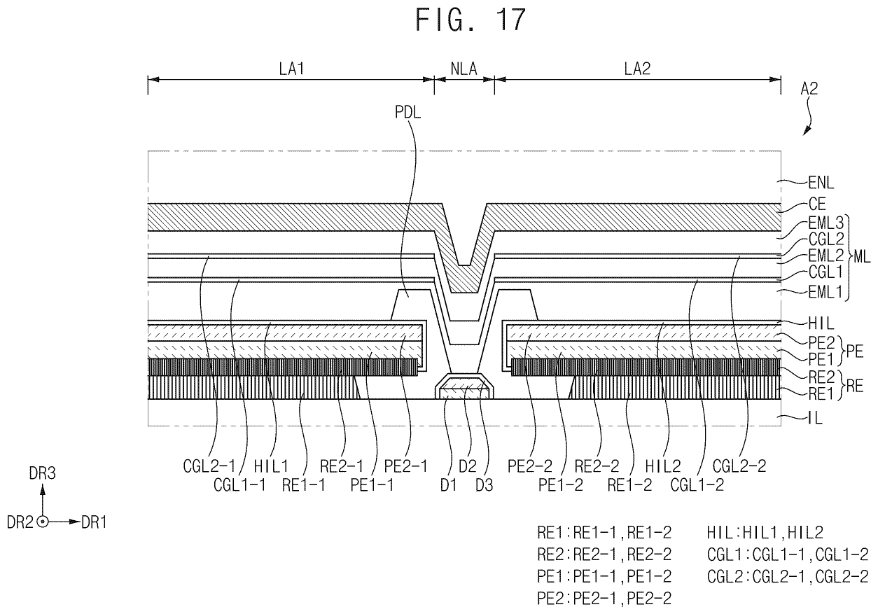

FIG. 16 is a schematic cross-sectional view of a display device taken along line I-I′ of FIG. 1 according to an embodiment. FIG. 17 is a schematic enlarged cross-sectional view illustrating A2 area of FIG. 16.

Components of the display device DD described with reference to FIGS. 16 and 17 are substantially a same as components of the display device DD described with reference to FIGS. 2 and 3 except for a pixel defining layer PDL.

Hereinafter, content overlapping content described with reference to FIGS. 2 and 3 will be omitted or simplified.

Referring to FIGS. 16 and 17, a pixel defining layer PDL may be disposed in the non-light emitting area NLA on the insulating structure IL. The pixel defining layer PDL may cover a portion of the hole auxiliary layer HIL. The pixel defining layer PDL may fill the space between the 1-1 reflective electrode RE1-1 and the 1-2 reflective electrode RE1-2.

In an embodiment, at least one opening may be defined in the pixel defining layer PDL. The opening may expose a portion of an upper surface of the third dummy layer D3. However, the disclosure may not be limited to this, and in case that the first, second, and third dummy layers D1, D2, and D3 are not formed on the insulating structure IL, the opening may expose a portion of an upper surface of the insulating structure IL.

In an embodiment, the pixel defining layer PDL may include an organic insulating material. In an embodiment, the pixel defining layer PDL may further include a light blocking material. The light blocking material may be a black dye, a black pigment, or the like, and may include a metal (e.g., a carbon black, a chrome, and the like.) or a metal oxide. Accordingly, the pixel defining layer PDL may block light.

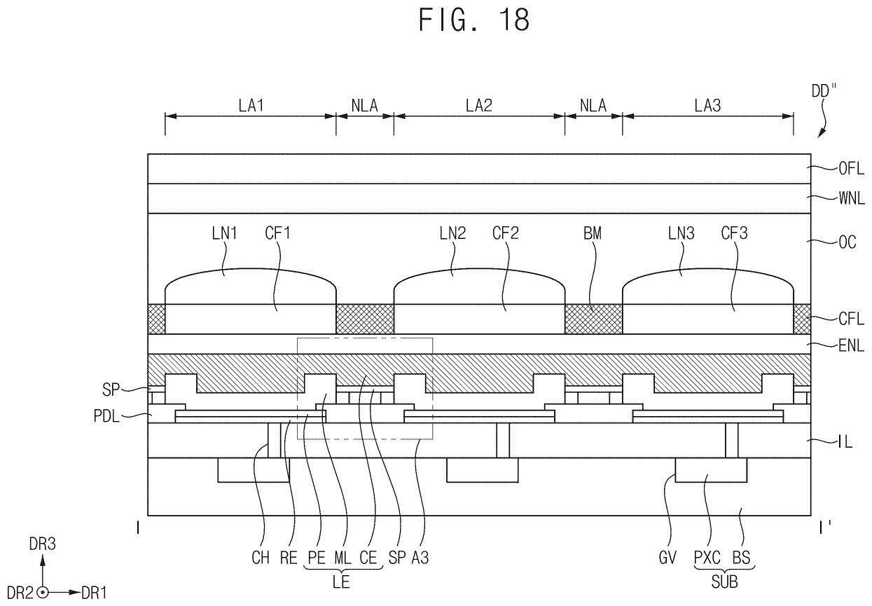

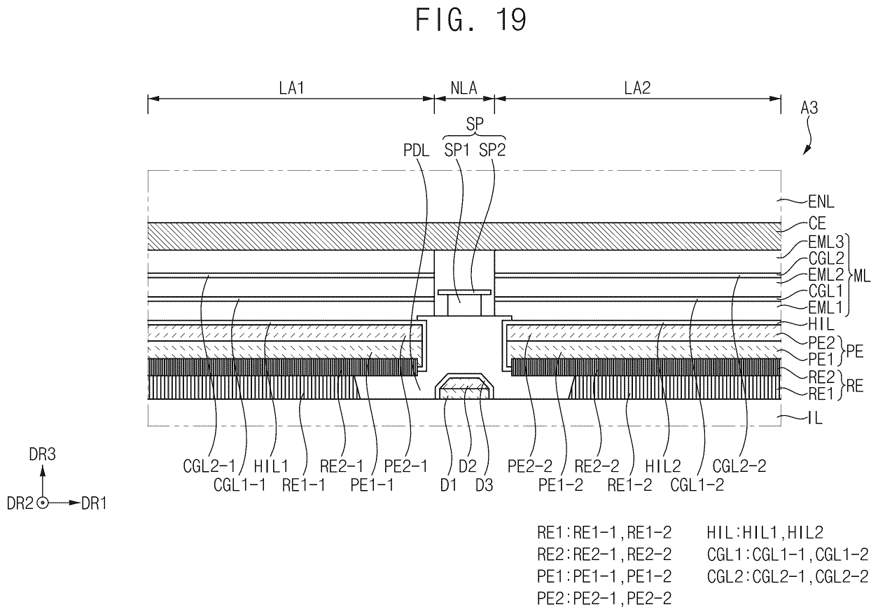

FIG. 18 is a schematic cross-sectional view of a display device taken along line I-I′ of FIG. 1 according to an embodiment. FIG. 19 is a schematic enlarged cross-sectional view illustrating A3 area of FIG. 18.

Components of the display device DD described with reference to FIGS. 18 and 19 are same as components of the display device DD described with reference to FIGS. 2 and 3 except for the pixel defining layer PDL, a separator SP, and the first to third light emitting layers EML1, EML2, and EML3.

Hereinafter, content overlapping content described with reference to FIGS. 2 and 3 will be omitted or simplified.

Referring to FIGS. 18 and 19, the pixel defining layer PDL may fill a space between the reflective electrode RE and the pixel electrode PE overlapping the first light emitting area LA1 and the reflective electrode RE and the pixel electrode PE overlapping the second light emitting area LA2. The pixel defining layer PDL may not have an opening defined to expose an upper surface of the third dummy layer D3 or an upper surface of the insulating structure IL. The pixel defining layer PDL may have a substantially flat upper surface.

The separator SP may be disposed on the pixel defining layer PDL. The separator SP may overlap the non-light emitting area NLA in a plan view. The separator SP may disconnect the first, second, third light emitting layers EML1, EML2, and EML3 in the non-light emitting area NLA. The separator SP may include a first separator SP1 and a second separator SP2.

The first separator SP1 may be disposed on the pixel defining layer PDL. The second separator SP2 may be disposed on the first separator SP1. In an embodiment, a width of the second separator SP2 in the first direction DR1 may be greater than a width of the first separator SP1 in the first direction DR1. In an embodiment, the first separator SP1 and the second separator SP2 may have a T-shape in a cross-sectional view. However, the disclosure may not be limited to this, and the width of the second separator SP2 in the first direction DR1 may be less than or be substantially same as the width of the first separator SP1 in the first direction DR1.

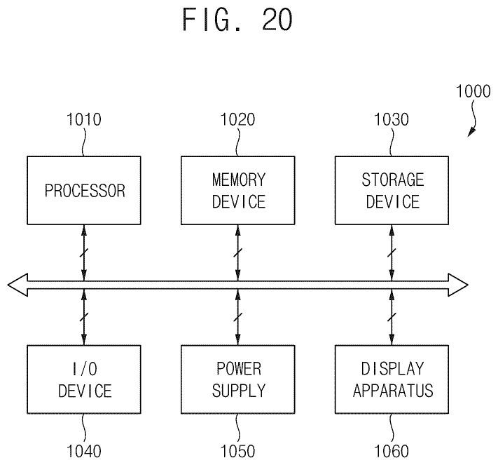

FIG. 20 is a block diagram illustrating an electronic device according to an embodiment.

Referring to FIG. 20, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIG. 1. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

The display device and the method according to the embodiments may be applied to an electronic device included in a computer, a notebook, a mobile phone, a smartphone, a smart pad, a PMP, a PDA, an MP3 player, or the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate including a first light emitting area, a second light emitting area spaced apart from the first light emitting area in a first direction, and a non-light emitting area located between the first light emitting area and the second light emitting area;
a first reflective electrode disposed in the first light emitting area on the substrate;
a second reflective electrode disposed in the second light emitting area on the substrate and spaced apart from the first reflective electrode in the first direction;
a first pixel electrode disposed in the first light emitting area on the first reflective electrode and having a width greater than a width of first reflective electrode in the first direction;
a second pixel electrode disposed in the second light emitting area on the second reflective electrode, spaced apart from the first pixel electrode in the first direction, and having a width greater than a width of second reflective electrode in the first direction;
a first hole auxiliary layer disposed in the first light emitting area on the first pixel electrode;
a second hole auxiliary layer disposed in the second light emitting area on the second pixel electrode and spaced apart from the first hole auxiliary layer in the first direction;
at least one light emitting layer disposed on the first hole auxiliary layer and the second hole auxiliary layer; and
a common electrode disposed on the at least one light emitting layer in the first light emitting area, the second light emitting area, and the non-light emitting area.

2. The display device of claim 1, wherein
the first pixel electrode includes:
a first lower pixel electrode disposed on the first reflective electrode; and
a first upper pixel electrode disposed on the first lower pixel electrode, and
the second pixel electrode includes:
a second lower pixel electrode disposed on the second reflective electrode; and
a second upper pixel electrode disposed on the second lower pixel electrode.

3. The display device of claim 2, wherein the first lower pixel electrode includes silver (Ag).

4. The display device of claim 2, wherein the second upper pixel electrode includes indium tin oxide (ITO).

5. The display device of claim 2, wherein
a thickness of the first lower pixel electrode is greater than a thickness of the first upper pixel electrode, and
a thickness of the second lower pixel electrode is greater than a thickness of the second upper pixel electrode.

6. The display device of claim 5, wherein the thickness of each of the first lower pixel electrode and the second lower pixel electrode is in a range of about 200 Å to about 1000 Å.

7. The display device of claim 5, wherein the thickness of each of the first upper pixel electrode and the second upper pixel electrode is in a range of about 30 Å to about 100 Å.

8. The display device of claim 1, wherein the at least one light emitting layer includes:
a first light emitting layer disposed between the first hole auxiliary layer and the second hole auxiliary layer;
a second light emitting layer disposed on the first light emitting layer;
a first charge generating layer disposed between the first light emitting layer and the second light emitting layer in the first light emitting area; and
a second charge generating layer disposed between the first light emitting layer and the second light emitting layer in the second light emitting area.

9. The display device of claim 8, wherein the first charge generating layer and the second charge generating layer are spaced apart from each other in the first direction.

10. The display device of claim 8, wherein the at least one light emitting layer further includes:
a third light emitting layer disposed on the second light emitting layer;
a third charge generating layer disposed between the second light emitting layer and the third light emitting layer in the first light emitting area; and
a fourth charge generating layer disposed between the second light emitting layer and the third light emitting layer in the second light emitting area.

11. The display device of claim 10, wherein the third charge generating layer and the fourth charge generating layer are spaced apart from each other in the first direction.

12. The display device of claim 1, wherein
the first reflective electrode includes:
a first lower reflective electrode disposed on the substrate; and
a first upper reflective electrode disposed on the first lower reflective electrode, and
the second reflective electrode includes:
a second lower reflective electrode disposed on the substrate; and
a second upper reflective electrode disposed on the second lower reflective electrode.

13. The display device of claim 12, wherein in a cross-sectional view,
the first lower reflective electrode has an undercut shape under the first upper reflective electrode, and
the second lower reflective electrode has an undercut shape under the second upper reflective electrode.

14. The display device of claim 1, further comprising:
a pixel defining layer disposed in the non-light emitting area, a portion of the first light emitting area, and a portion of the second light emitting area on the substrate, and covering a portion of an upper surface of the hole auxiliary layer and a side surface of the hole auxiliary layer.

15. The display device of claim 14, further comprising:
a separator disposed in the non-light emitting area on the pixel defining layer.

16. A method of manufacturing a display device, the method comprising:
forming a first reflective electrode in a first light emitting area on a substrate including the first light emitting area, a second light emitting area spaced apart from the first light emitting area in a first direction, and a non-light emitting area located between the first light emitting area and the second light emitting area;
forming a second reflective electrode spaced apart from the first reflective electrode in the first direction in the second light emitting area on the substrate;
forming a first pixel electrode on the first reflective electrode;
forming a second pixel electrode spaced apart from the first pixel electrode in the first direction on the second reflective electrode;
forming a first hole auxiliary layer on the first pixel electrode;
forming a second hole auxiliary layer spaced apart from the first hole auxiliary layer in the first direction on the second pixel electrode;
forming a first light emitting layer on the first hole auxiliary layer and the second hole auxiliary layer;
forming a first charge generating layer in the first light emitting area on the first light emitting layer;
forming a second charge generating layer spaced apart from the first charge generating layer in the first direction in the second light emitting area on the first light emitting layer; and
forming a second light emitting layer on the first charge generating layer and the second charge generating layer.

17. The method of claim 16, wherein
the first reflective electrode includes:
a lower reflective electrode disposed on the substrate; and
an upper reflective electrode disposed on the lower reflective electrode, and the forming of the first reflective electrode includes:
forming a preliminary lower reflective electrode in the first light emitting area on the substrate;
forming the upper reflective electrode in the first light emitting area on the preliminary lower reflective electrode; and
removing a portion of the preliminary lower reflective electrode so that a width of the preliminary lower reflective electrode in the first direction is less than a width of the upper reflective electrode in the first direction.

18. The method of claim 17, wherein in the removing of the portion of the preliminary lower reflective electrode, the preliminary lower reflective electrode is etched to have an undercut shape under the upper reflective electrode in a cross-sectional view to form the lower reflective electrode.

19. The method of claim 16, wherein in the forming of the first hole auxiliary layer and the forming of the second hole auxiliary layer,
a deposition material constituting the first hole auxiliary layer and the second hole auxiliary layer is applied over the first light emitting area, the second light emitting area, and the non-light emitting area, and
the first hole auxiliary layer and the second hole auxiliary layer are spaced apart from each other after the deposition material is applied.

20. The method of claim 16, wherein in the forming of the first charge generating layer and the forming of the second charge generating layer,
a deposition material constituting the first charge generating layer and the second charge generating layer is applied on the first light emitting layer, and
the first charge generating layer and the second charge generating layer are spaced apart from each other after the deposition material is applied.

21. An electronic device comprising:
a display device; and
a power supply configured to provide power to the display device,
wherein the display device comprises:
a substrate including a first light emitting area, a second light emitting area spaced apart from the first light emitting area in a first direction, and a non-light emitting area located between the first light emitting area and the second light emitting area;
a first reflective electrode disposed in the first light emitting area on the substrate;
a second reflective electrode disposed in the second light emitting area on the substrate and spaced apart from the first reflective electrode in the first direction;
a first pixel electrode disposed in the first light emitting area on the first reflective electrode and having a width greater than a width of first reflective electrode in the first direction;
a second pixel electrode disposed in the second light emitting area on the second reflective electrode, spaced apart from the first pixel electrode in the first direction, and having a width greater than a width of second reflective electrode in the first direction;
a first hole auxiliary layer disposed in the first light emitting area on the first pixel electrode;
a second hole auxiliary layer disposed in the second light emitting area on the second pixel electrode and spaced apart from the first hole auxiliary layer in the first direction;
at least one light emitting layer disposed on the first hole auxiliary layer and the second hole auxiliary layer; and
a common electrode disposed on the at least one light emitting layer in the first light emitting area, the second light emitting area, and the non-light emitting area.
